(19) United States
(12) Patent Application Publication
(10) Pub. No.: US 2009/0306915 A1
(43) Pub. Date: Dec. 10, 2009

(54) Method for predicting the power capacity of electrical energy stores

(76) Inventor: Eberhard Schoch, Stuttgart-Feuerbach (DE)

Correspondence Address: KENYON & KENYON LLP, ONE BROADWAY, NEW YORK, NY, 10004, US

(21) Appl. No.: 11/989,063

(22) PCT Filed: Oct. 19, 2006
(86) PCT No.: PCT/EP2006/067563

§ 371 Date: Mar. 17, 2009

(30) Foreign Application Priority Data
Oct. 21, 2005 (DE) 10 2005 050 563.5

(51) Int. Cl. G01R 31/36; G01N 27/416

(52) U.S. Cl. 702/63; 324/427

(57) ABSTRACT

A method and a corresponding device are described for predicting the power capacity of an electrical energy store, such as a battery in a vehicle, in which, with the aid of a mathematical model for the energy store, its state variables and parameters are continuously adjusted, and thereby a charge and discharge power capability is estimated and predicted.

### FIELD OF THE INVENTION

The present invention relates to a method for predicting the power capacity of electrical energy stores. In particular, variables are ascertained of an electrical energy store or power store for a motor vehicle.

### BACKGROUND INFORMATION

Information about current, maximally available discharge power of the battery, that is as exact as possible, is important for electrical energy management in vehicles. This applies especially to electric and hybrid vehicles, and vehicles having start and stop function and recuperative intervention, in which the current, maximally available discharge power of the electric energy store, provided for the engine start, electrical drive, and for the supply of other electrical users, as well as the currently maximally available charge power of the electrical energy store used for the feedback of the braking energy are of decisive importance.

Various methods are known for ascertaining the power capacity of electrical energy stores. Most methods are limited to the determination of the available discharge power. German Patent Application No. DE 103 01 823, for example, describes the discharge power capacity is evaluated in light of a voltage response, precalculated with the aid of a model, to a specified load current profile. However, this attempt does not yet deliver any reply to the question as to what maximum power the energy store is able to supply at a specified minimum admissible vehicle electrical system voltage.

For the evaluation of the recuperation capacity, the charge power capacity and the charge acceptance of an energy store, methods are provided that are supported by characteristics maps as a function of the charge state and the temperature and/or the impedance of the energy store. German Patent Application No. DE 198 49 055 describes such methods, for example. However, further limiting factors for the charge power capacity, such as polarization, acid stratification or icing of the energy store, especially of a lead battery, are not considered.

### SUMMARY

By contrast, an example method according to the present invention may make possible an improved determination of the relevant variables of the energy store. This advantage is achieved with the aid of a mathematical model of the energy store, whose state variables and parameters are continuously adapted. This makes possible an accurate prediction of the maximum charge and discharge power of the electrical energy store, particularly of a lead accumulator used in a motor vehicle, by taking into consideration all the relevant influential variables, such as the temperature, the charge state, the Ohmic internal resistance, polarizations, acid stratification, aging and icing.

The example methods may advantageously make possible the model-based prediction of the current maximum charge and discharge power of an electrical energy store, particularly under consideration of the admissible maximum charge voltage and the minimum vehicle electrical system voltage. In an advantageous refinement, additional specifications for the admissible maximum charge and/or discharge current and/or the minimum or maximum charge state may be taken into consideration.

Besides the prediction of the current available charge and discharge power, the example method according to the present invention is also in a position, in a particularly advantageous manner, of determining the charge and discharge power to be expected at any specifiable temperatures and charge states. The available charge power of a battery, having an SOC (state of charge)=50% for a cold start at −18° C., may be ascertained, for example. The charge and discharge power referred to a specified fixed temperature and a specified charge state may also be used as a measure of the battery aging SOH (state of health).

### BRIEF DESCRIPTION OF THE DRAWINGS

The present invention is represented in the figures and explained in greater detail below.

FIG. 1 shows an equivalent circuit diagram for lead accumulators.

FIG. 2 shows a structural illustration of the power prediction.

FIG. 3 shows a flow chart for the prediction of discharge power.

FIG. 4 shows a flow chart of the prediction of the charge power.

### DETAILED DESCRIPTION OF EXAMPLE EMBODIMENTS

### Mathematical Model of the Energy Store

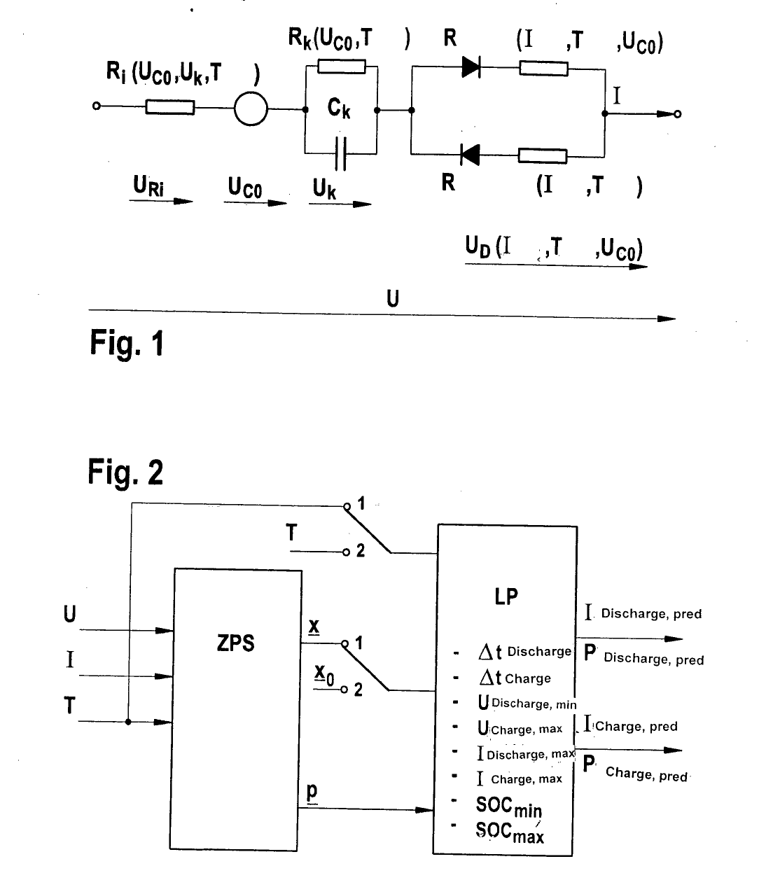

FIG. 1 shows the equivalent circuit diagram of a lead accumulator, used for the power prediction. The counting direction of battery current I_{Batt} was chosen to be positive for charging and negative for discharging.

### Voltages:

U_{Batt}=Terminal voltage of the battery
U_{Ri}=Ohmic voltage drop
U_{c0}=static voltage (˜average acid concentration in the battery, a measure for the charge state)
Uₖ=concentration polarization (˜deviation of the acid concentration at the point of reaction from the average value in the battery)
U_{D}(I_{Batt}, T_{Batt}, U_{c0})=steady state charge transfer polarization, as a function of the battery current and the acid temperature, and in the charge case also the static voltage

### Equivalent Circuit Diagram Components:

Rᵢ(U_{C0}, Uₖ, T_{Batt})=Ohmic internal resistance, as a function of the static voltage, the concentration polarization and the acid temperature
Rₖ(U_{C0}, T_{Batt})=acid diffusion resistance, as a function of the static voltage and the acid temperature
τₖ=Rₖ*Cₖ=time constant of acid diffusion (is assumed to be constant in the order of magnitude of 10 min)
R_{D, discharging}(I_{Batt}, T_{Batt})=current-dependent and temperature-dependent resistance of the charge transfer polarization during discharge
R_{D, Charging}(I_{Batt}, T_{Batt}, U_{C0})=current-dependent, temperature-dependent and static voltage-dependent resistance of charge transfer polarization during charging

### Characteristics Maps and Parameters:

### Ohmic Internal Resistance:

Rᵢ(U_{C0},Uₖ,T_{Batt})=Rᵢ₀(T_{Batt})*(1+R_{i,fakt}*(U_{C0max}−U_{C0})/(U_{C0}+Uₖ−U_{e,grenz}))

where
Rᵢ₀ (T_{Batt})=Rᵢ₀₂₅/(1+TK_{Lfakt}*(T_{Batt}−25° C.)
U_{e,grenz}=max (U_{C0,grenz}, U_{C0,Eis}(T_{Batt}))
U_{C0,Eis}(T_{Batt})=U_{C0,Eis0}+C_{1,Eis}*T_{Batt}+C_{2,Eis}*T_{Batt}+C_{3,Eis}*T_{Batt}³
Rᵢ₀₂₅=Ohmic internal resistance at full charge and T_{Batt}=25° C.
TK_{Lfakt}=Temperature coefficient of the battery conductivity
R_{i, fakt}=characteristics map parameters
U_{C0max}=maximum static voltage of the completely charged battery
U_{e,grenz}=minimum static voltage at discharge conclusion
U_{C0,grenz}=minimum static voltage at discharge conclusion without consideration of battery icing
U_{C0,Eis}(T_{Batt})=temperature-dependent static voltage limit for battery icing (icing characteristics line)
U_{C0,Eis0}, C_{1,Eis}, C_{2,Eis}, C_{3,Eis}=parameters of the icing characteristics line

### Acid Diffusion Resistance

Rₖ(U_{C0},T_{Batt})=Rₖ₀(T_{Batt})*(1+R_{k,fakt1}*(U_{C0max}−U_{C0})+R_{k,fakt2}*(U_{C0max}−U_{C0}) ²)

where

Rₖ₀(T_{Batt})=Rₖ₀₂₅*exp(−(E_{Rk0}/J)/8.314*(1/(273.15+T_{Batt}/° C.)−1/298.15)) (Arrhenius approach)
Rₖ₀₂₅=acid diffusion resistance at full charge and T_{Batt}=25° C.
E_{Rk0}=activation energy
R_{k,fakt1}R_{k,fakt2}=polynomial coefficients

### Stationary Charge Transfer Polarization

### Discharging:

U_{D,Ela}(I_{Batt},T_{Batt})=U_{D0,Ela}(T_{Batt})*ln (I_{Batt}/I_{D0,Ela}),

where
I_{D0,Ela}=−1A, I_{Batt}<I_{D0,Ela}

U_{C0,Eis}(T_{Batt})=U_{D025,Ela}*(1+TK_{UD01}*(T_{Batt}−25° C.)+TK_{UD02}*(T_{Batt}−25° C.)²+ . . . TK_{UD03}*(T_{Batt}−25° C.)³)
U_{D025,Ela}=stationary charge transfer voltage at I_{Batt}=e*I_{D0,Ela} und T_{Batt}=25° C.
I_{D0,Ela}=charge transfer current for U_{D}=0V
TK_{UD01}, TK_{UD02}, TK_{UD03}=Temperature coefficients first, second and third order of charge transfer polarization

### Charging:

U_{D,Lad}(I_{Batt},T_{Batt},U_{C0})=U_{D0,Lad}(T_{Batt})*sqrt(I_{Batt}/I_{D0,Lad}*(U_{C0max}−U_{C0min})/(U_{C0max}−U_{C0}))

where
I_{D0,Lad}=1A, I_{Batt}>0A

U_{D0,Lad}(T_{Batt})=U_{D025,Lad}* . . . sqrt exp(−(E_{uD0,Lad}/J)/8.314*(1/298.15−1/(273.15+T_{Batt}/° C.)))))
U_{D025,Lad}=stationary charge transfer voltage at I_{Batt}=I_{D0,Lad}, T_{Batt}=25° C. und U_{C0}=U_{C0min}
E_{uD0,Lad}=activation energy
U_{C0min}=minimum static voltage of the completely discharged battery

Required state variables and parameters for the prediction of discharge and charge power

The currently available discharge and charge power is able to be predicted with the aid of the above-mentioned model equations, and under the assumption that the state variables and the parameters of the prediction model correspond to those of the actual battery. The variables being looked for may be determined, for instance, by comparison of the model in light of the measured variables current, voltage and temperature, using a Kalman filter.

For the prediction of the current discharge/charge power, in each case the current state variables of the prediction model, that is, the static voltage U_{C0} and the concentration polarization have to be known. Therefore, the state estimator has to ascertain at least the state vector x=[U_{C0}, Uₖ]. An improvement in the power estimation is made possible by additional estimation of charge transfer polarization U_{D}.

Furthermore, at least the strongly aging-dependent parameters of the prediction model have to be adjusted. These are the characteristics curve parameters Rᵢ₀₂₅ and U_{C0,grenz} of the Ohmic internal resistance and the acid diffusion resistance Rₖ₀₂₅ at full charge and T_{Batt}=25° C. The prediction may be further improved by the additional adjustment of characteristics curve parameters U_{D025,Ela} and U_{D025,Lad} of the charge transfer polarization. Using this, one best obtains the parameter vector

p=[Rᵢ₀₂₅,U_{C0,grenz}, Rₖ₀₂₅,U_{D025,Ela}, U_{D025,Lad}]

with the aid of suitable parameter estimation methods.

Prediction of the maximum available discharge power and charge power (power predictor)

FIG. 2 shows the structure in principle of the power prediction. A state estimator and parameter estimator (e.g., a Kalman filter) estimates continuously the current state variables required for the power prediction and the parameters of the electrical energy store by which the prediction model is initiated. Subsequently, with the aid of the model equations and the specifications for the duration of the discharge/charge pulse, the admissible minimum and maximum battery voltage, the admissible maximum discharge and charge current as well as the minimum and maximum charge state, one may calculate the available discharge/charge power.

If one wants to find out the available charge/discharge power at other temperatures (e.g., a cold start temperature of −18° C. or a nominal temperature of 25° C.) and/or charge states (e.g., full charge) as the current one, T_{Batt} and static voltage U_{C0} are initiated in the power predictor using the corresponding specified values T_{Batt0} and x₀ instead of the current values. The power values ascertained in this manner at the same time also supply a measure for the battery's aging (SOH=state of health).

The following conditions and assumptions are met for the determination of the discharge and charge power with respect to a constant current discharge or charge pulse:

### DEFINITIONS

Δt_{Ela}=duration of the discharge pulse in s
Δt_{Lad}=duration of the discharge pulse in s
U_{Ela,min}=minimal admissible vehicle electrical system voltage in V
U_{Lad,max}=maximum admissible battery(−charging) voltage in V
I_{Ela,max}=maximum admissible discharge current in A
I_{Lad,max}=maximum admissible charge current in A
SOCₘᵢₙ=minimum admissible charge state in %
SOCₘₐₓ=minimum admissible charge state in %

Using the SOC definition of static voltage U_{C0}:

SOC=100*(U_{C0}−U_{C0,min})/(U_{C0,max}−U_{C0,min})

Δt_{Ela} and =Δt_{dLad} should be selected to be so small that the charge state change because of the current pulse is negligible (U_{C0}=const) and so large, that the charge transfer polarization during the current pulse assumes its stationary value (order of magnitude 1-10 s).

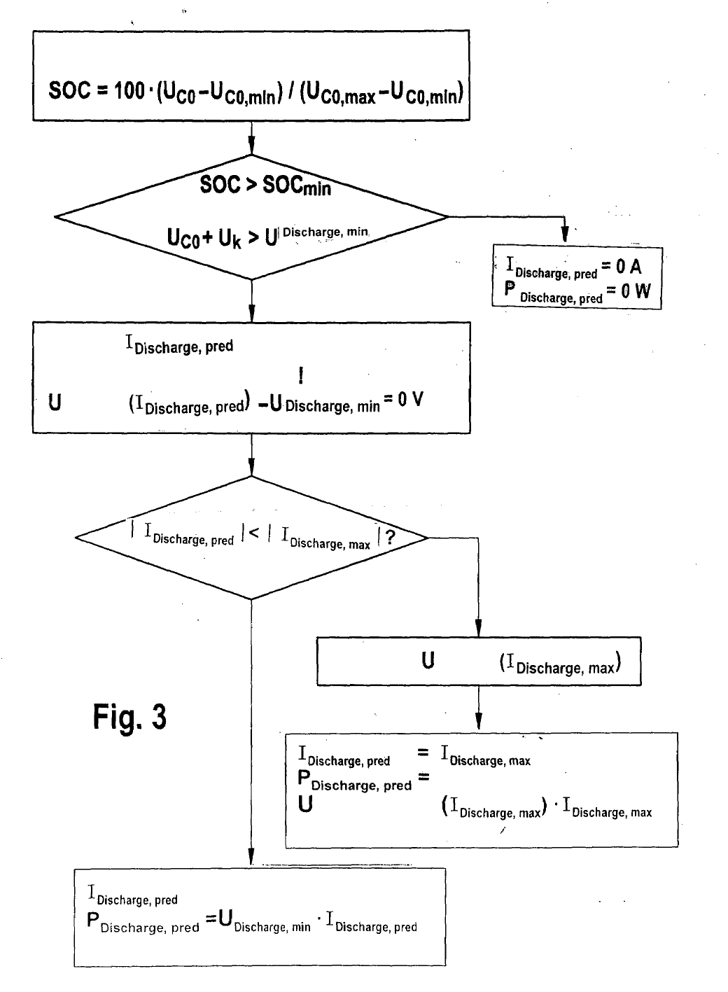

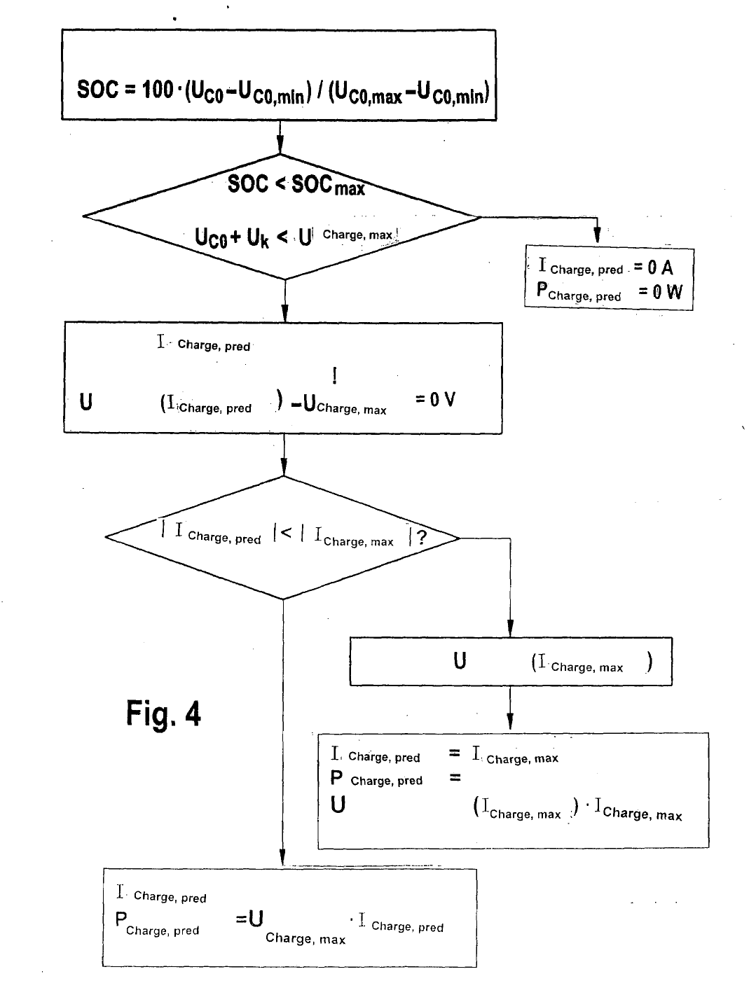

What is shown is the sequence of the power prediction, or rather, the sequence to the prediction of the maximum available discharge and charge power in two flow charts. The sequence of the power prediction, in this instance, is shown separately for discharge and charge power in FIGS. 3 and 4.

Prediction of the maximum available discharge power

Discharge current I_{Ela,pred} and discharge power P_{Ela,pred} are ascertained by determining the zero value of

!

U_{Batt,Modell}(I_{Ela,pred})−U_{Ela,min}=0

the battery voltage U_{Batt,Modell}(I_{Ela,pred}), that sets in at the end of the discharge current pulse of duration Δt_{Ela} being calculated with the aid of the prediction model that has already been described:

U_{Batt,Modell}(I_{Ela,pred})=U_{C0,pred}+U_{k,pred}+ . . . Rᵢ(U_{C0,pred},U_{k,pred},T_{Batt})*I_{Ela,pred}+U_{k,pred}+U_{D,Ela}(I_{Ela,pred},T_{Batt})

where
U_{C0,pred}=U_{C0} (=> charge state change by current pulse ignored)

U_{k,pred}=Rₖ(U_{C0,pred},T_{Batt})*I_{Ela,pred}+ . . . (Uₖ−Rₖ(U_{C0,pred},T_{Batt})*I_{Ela,pred})*exp(−Δt_{Ela}/τₖ)

(=> solution of the differential equation for the RC-member Rₖ∥Cₖ)

After inserting the relationships mentioned, I_{Ela,pred} is able to be calculated. Because of the nonlinear function U_{D,Ela}(I_{Ela,pred},T_{Batt}), this can only be done numerically with the aid of a null search method, such as a method of false positions.

The maximum available discharge power is then

P_{Ela,pred}=U_{Ela,min}*I_{Ela,pred}

Before the null position calculation one should check whether there is a solution I_{Ela,pred}<0A in the first place. To do this, it is tested whether the condition:

U_{Batt,Modell}(I_{Ela,pred}=0A,Δt_{Ela}=0s)=U_{C0}+Uₖ>U_{Ela,min} is satisfied.

If not, I_{Ela,pred}=0A and P_{Ela,pred}=0W are output.

Furthermore, one should check whether the definitions for the maximum admissible discharge current I_{Ela,max} and the minimum charge state SOCₘᵢₙ are being maintained.

If |I_{Ela,pred}|>|I_{Ela,max}|, I_{Ela,pred} is set=I_{Ela,max}, und U_{Batt,Modell}(I_{Ela,max}) is calculated, so that for the maximum discharge power,

P_{Ela,pred}=U_{Batt,Modell}(I_{Ela,max})*I_{Ela,max}

results.

The maintaining of the minimum charge state is checked using the condition:

SOC=100*(U_{C0}−U_{C0,min})/(U_{C0,max}−U_{C0,min})>SOCₘᵢₙ

If the condition is not satisfied, I_{Ela,pred}=0A und P_{Ela,pred}=0W are output.

It is to be observed that

SOCₘᵢₙ>SOC_{grenz}=100*(U_{e,grenz}−U_{C0,min})/(U_{C0,max}−U_{C0,min}) has to be specified (see formula for Rᵢ in section 2.4.1).

### Prediction of the Maximum Available Charge Power

In a manner equivalent to the ascertainment of the maximum discharge current and the maximum discharge power, maximum charge current I_{Ela,pred} and the maximum charge power P_{Lad,pred} are ascertained by determining the null position of

!

U_{Batt,Modell}(I_{Ela,pred})−U_{Ela,min}=0

the battery voltage U_{Batt,Modell}(I_{Ela,pred}), that sets in at the end of the charge current pulse of duration Δt_{Lad}, being calculated again with the aid of the prediction model that has already been described:

U_{Batt,Modell}(I_{Lad,pred})=U_{C0,pred}+U_{k,pred}+Rᵢ(U_{C0,pred},U_{k,pred},T_{Batt})*I_{Lad,pred}+U_{k,pred}+ . . . U_{D,Lad}(I_{Lad,pred},T_{Batt}, U_{C0,pred})

where:
U_{C0,pred}=U_{C0} (=>charge state change by current pulse ignored)

U_{k,pred}=Rₖ(U_{C0,pred},T_{Batt})*I_{Lad,pred}+ . . . (Uₖ−Rₖ(U_{C0,pred},T_{Batt})*I_{Lad,pred})*exp(−Δt_{Lad}/τₖ)

(=> solution of the differential equation for the RC-member Rₖ∥Cₖ)

After inserting the relationships mentioned, I_{Ela,pred} is able to be calculated. Because of the nonlinear function U_{D,Lad}(I_{Lad,pred},T_{Batt},U_{C0,pred}), this can again only be done numerically with the aid of a null search method, such as a method of false positions.

The maximum available discharge power is then

P_{Lad,pred}=U_{Lad,max}*I_{Lad,pred}

Before the null position calculation one should check whether there is a solution to I_{Lad,pred}>0A at all. To do this, it is tested whether the condition:

U_{Batt,Modell}(I_{Lad,pred}=0A,Δt_{Lad}=0S)=U_{C0}+Uₖ<U_{Lad,max} is satisfied.

If not, I_{Lad,pred}=0A and P_{Lad,pred}=0W are output.

Furthermore, one should check whether the definitions of the maximum admissible charge current I_{Lad,max} and the maximum charge state SOCₘₐₓ are being maintained.

If |I_{Lad,pred}|>|I_{Lad,max}|, I_{Lad,pred} is set=I_{Lad,max} and U_{Batt,Modell}(I_{Lad,max}) is calculated, so that for the maximum charge power one obtains:

P_{Ela,pred}=U_{Batt,Modell}(I_{Ela,max})*I_{Ela,max}

The maintaining of the maximum charge state is checked using the condition:

SOC=100*(U_{C0}−U_{C0,min})/(U_{C0,max}−U_{C0,min})<SOCₘₐₓ≦100%

If the condition is not satisfied, I_{Lad,pred}=0A und P_{Lad,pred}=0W are output.

The methods described may be modified in a suitable manner, if necessary. They preferably run in a suitably equipped control device, for instance, a control unit for battery state detection to which the battery is connected, or a vehicle electrical system manager in a vehicle.

A further possibility for their application is in an IBS (intelligent battery sensor) and/or in body computers, or as software module within the scope of an electrical battery management.

1-11. (canceled)

12. A method for predicting the power capacity of an electrical energy store, comprising:
forming a mathematical model of the energy store;
continuously adjusting state variables and parameters of the model; and
predicting a maximum charge and a discharge power using the model.

13. The method as recited in claim 12, wherein relevant influential variables including at least one of temperature, charge state, Ohmic internal resistance, polarizations, acid stratification, age, and icing, are taken into consideration in the model.

14. The method as recited in claim 12, wherein a state estimator and parameter estimator is used for power prediction which continuously estimates currently required state variables.

15. The method as recited in claim 14, wherein the state estimator and parameter estimator is a Kalman filter.

16. The method as recited in claim 12, wherein at least one of a maximum admissible charge voltage and a minimum vehicle electrical system voltage, are taken into consideration in the model.

17. The method as recited in claim 16, wherein additional definitions for the at least one of an admissible maximum charge, a discharge current, a minimum, and a maximum charge state, are taken into consideration.

18. The method as recited in claim 12, wherein at least one of a currently available charge, and a discharge power are determined using the model.

19. The method as recited in claim 16, wherein at least one of a charge power and a discharge power to be expected at any at least one of specifiable temperatures, and charge states are determined using the model.

20. The method as recited in claim 12, wherein at least one of a charge power and a discharge power ascertained with reference to a fixed specified temperature are used as a measure for an aging of the energy store.

21. The method as recited in claim 12, wherein the energy store is a battery for a vehicle.

22. A device for predicting a power capacity of an electrical energy store, comprising:
a control device adapted to form a mathematical model of the energy store, continuously adjust state variables and parameters of the model, and predict a maximum charge and a discharge power using the model.

23. The device as recited in claim 22, wherein the control device includes a control unit, or is a component of an intelligent battery sensor or a body computer or a component of a software module for an electrical battery management.
